(19) United States
(12) Patent Application Publication
(10) Pub. No.: US 2010/0056411 A1
(43) Pub. Date: Mar. 4, 2010

(54) Treating liquid for photoresist removal and method for treating substrate

(76) Inventors: Takayuki Haraguchi, Kawasak-shi (JP); Kazumasa Wakiya, Kawasaki-shi (JP); Shigeru Yokoi, Kawasaki-shi (JP)

Correspondence Address: WENDEROTH, LIND & PONACK, L.L.P., 1030 15th Street, N.W.,, Suite 400 East, Washington, DC, 20005-1503, US

(21) Appl. No.: 12/591,048

(22) Filed: Nov. 5, 2009

Related U.S. Application Data
(63) Continuation of application No. 12/382,231, filed on Mar. 11, 2009, now abandoned.
Application No. 12/382,231 is a continuation of application No. 12/155,386, filed on Jun. 3, 2008, now abandoned.
Application No. 12/155,386 is a continuation of application No. 11/245,113, filed on Oct. 7, 2005, now abandoned.

(30) Foreign Application Priority Data
Oct. 8, 2004 (JP) 2004-296606

(51) Int. Cl. G03F 7/42

(52) U.S. Cl. 510/176

(57) ABSTRACT

Disclosed are a treating liquid for photoresist removal, containing (a) an oxidizing agent (e.g., aqueous hydrogen peroxide), (b) at least one selected from alkylene carbonates and their derivatives (e.g., propylene carbonate), and (c) water; and a method for treating with the treating liquid a substrate having a photoresist film deteriorated after dry-etching treatment thereof or a substrate optionally subjected to plasma-ashing treatment after the dry-etching treatment, and then treating it with a photoresist-stripping liquid for stripping off the photoresist.

### BACKGROUND OF THE INVENTION

1. Field of the Invention

The present invention relates to a treating liquid for photoresist removal, which is used for removal of a photoresist film deteriorated after dry-etching treatment, and to a method for treating a substrate using the treating liquid.

2. Description of Related Art

A semiconductor device, such as IC and LSI, is produced in the following process. A photoresist is uniformly coated on an electroconductive metallic film, an insulating film or a low dielectric material film formed on a substrate, such as a silicon wafer, by CVD vapor deposition process or the like. The photoresist is selectively subjected to exposure and development to form a photoresist pattern. The electroconductive metallic film, the insulating film or the low dielectric material film formed by CVD vapor deposition is selectively etched by using the photoresist pattern as a mask to form a minute circuit, and the photoresist layer thus becoming unnecessary is then removed with a remover liquid.

With the recent tendency toward the increase in the density of integrated circuits, dry-etching is now a mainstream in the art that enables microetching to a higher density. After subjected to such dry-etching, a photoresist film changes to a deteriorated film. Recently, the treatment condition has become severer, and the deteriorated film has changed from an organic film to a film having an inorganic property, and it has become more difficult to remove the deteriorated film than before.

Further, the recent tendency in the art is toward the increase in the integration of semiconductor devices and the reduction in the size of chips, and therefore, wiring circuits are being much more micropatterned and multi-layered, and in that situation, some problems with semiconductor devices are pointed out such as wiring delay caused by the resistance of the metal layer used (wiring resistance) and the wiring capacity. Accordingly, use of metal such as copper (Cu) having a smaller resistance than that of aluminium (Al) that has heretofore been mainly used as a wiring material, has been proposed, and recently, two types of devices, one using Al wiring (Al-based metal wiring of Al or Al alloy) and another using Cu wiring (Cu-based metal wiring), have become used.

In Cu metal wiring, employed is a method of forming multi-level Cu wiring according to a dual-damascene process not including a step of Cu etching, since the etching resistance of Cu is low. One example of the dual-damascene process comprises forming Cu layer/low-dielectric layer (e.g., SiOC layer)/photoresist pattern on a substrate, dry-etching the low-dielectric layer through the photoresist pattern serving as a mask, then subjecting it to plasma-ashing treatment, and thereafter removing the photoresist pattern to thereby form via holes and wiring trenches that communicate with the via holes. With that, the via holes and the trenches are filled with Cu in a mode of electrolytic plating or the like to form multi-level wiring. Si deposition may readily occur, resulting from the low-dielectric layer, during the dry-etching treatment and the plasma-ashing treatment for forming the via-holes and the trenches, and this may form Si deposits around the opening of the trenches. In addition, deposits that result from photoresist such as deteriorated photoresist films may also form. Accordingly, if these deposits are not completely removed, then it causes a problem in that the yield in semiconductor production may lower. To that effect, heretofore, plasma-ashing treatment has been employed for removal of photoresist patterns and etching residues in ordinary patterning for metal wiring.

On the other hand, with the development of ultra-micropatterning technology, a material having a lower dielectric constant has become used for the low-dielectric layer to be formed on Cu wiring substrates, and at present, a process of using a low-dielectric layer that has a dielectric constant of at most 3 is being developed. It is said that the material of the type having such a low dielectric constant (low-k material) is poorly resistant to ashing or is not resistant to ashing, and when such a low-k material is used, a process not including a plasma-ashing step after dry-etching must be employed.

Accordingly, in the art of photolithography for producing advanced micropatterned multi-level semiconductor devices, it is a pressing need to develop a method excellent in removal of deteriorated photoresist film after dry-etching treatment in any process including or not including conventional plasma-ashing treatment, to the same level as or to a higher level than that in the conventional process of including a plasma-ashing step.

In the field of production of semiconductor devices, heretofore proposed are a cleaning liquid and a photoresist-removing liquid that contain an oxidizing agent (e.g. aqueous hydrogen peroxide) (for example, see References 1-8 listed below). Concretely mentioned are an aqueous solution of an oxidizing agent such as aqueous hydrogen peroxide or aqueous ozone; and a cleaning liquid and a removing liquid prepared by adding aqueous ammonia or quaternary ammonium hydroxide to it. However, these cleaning liquid and removing liquid described in References 1 to 8 are still problematic in that, even when they are used, they could not attain the dissolution (for promoted removal) of deteriorated photoresist films, which the invention intends to attain, or since the stability of the liquids themselves is poor, they could not be used in practical production lines.

Reference 9 listed below discloses a photoresist-removing liquid comprising, as a water-soluble organic solvent therein, an aprotic polar solvent, propylene carbonate, which, however, is not still on a satisfactory level that is at present required in the field of production of more micropatterned and multi-layered semiconductor devices.

Reference 1: JP-A-5-259140

Reference 2: JP-A-6-112178

Reference 3: JP-A-11-74180

Reference 4: JP-A-2000-56478

Reference 5: JP-A-2002-202617

Reference 6: JP-A-2003-124173

Reference 7: JP-A-2003-221600

Reference 8: JP-A-2004-4775

Reference 9: JP-A-11-16882

### SUMMARY OF THE INVENTION

The present invention has been made in consideration of the above-mentioned situation, and its object is to provide a treating liquid for photoresist removal having the advantages in that it can greatly improve the dissolution (for promoted removal) of photoresist films deteriorated after dry-etching treatment, irrespective of the presence or absence of plasma-ashing treatment for them, that its effect is stable, that, even when used for substrates with copper wiring and a low-dielectric layer formed thereon, it does not have any negative influence on the dielectric constant of the dielectric layer, and that it has good corrosion resistance; and to provide a method for treating a substrate using the treating liquid.

To solve the above-mentioned problems, the invention provides a treating liquid for photoresist removal, containing (a) an oxidizing agent, (b) at least one selected from alkylene carbonates and their derivatives, and (c) water.

The invention also provides a method for treating a substrate, which comprises treating a substrate having a photoresist film deteriorated after dry-etching treatment thereof or a substrate optionally subjected to plasma-ashing treatment after the dry-etching treatment, with the above-mentioned treating liquid for photoresist removal, and then treating it with a photoresist-stripping liquid for stripping off the photoresist.

### DETAILED DESCRIPTION OF THE INVENTION

The invention is described in detail hereinunder. In the following, the amount as referred to for compounding of components is in terms of a solid content, or that is, a substantial content of the component unless otherwise specifically indicated.

The treating liquid of the invention contains (a) an oxidizing agent, (b) at least one selected from alkylene carbonates and their derivatives, and (c) water.

The component (a) is preferably at least one of aqueous hydrogen peroxide (H₂O₂) and aqueous ozone (O₃). Regarding its concentration in the treating liquid, the oxidizing agent is preferably an aqueous solution thereof having a concentration of 0.1-35% by mass or so, more preferably 0.5-30% by mass or so. Defining the amount of the component (a) to fall within the range as above is especially effective for improving the capability of the treating liquid for better dissolution (for promoted removal) of deteriorated photoresist films after dry-etching treatment.

The component (b) includes lower alkylene carbonates such as ethylene carbonate and propylene carbonate, and their derivatives. The derivatives include alkyl-substituted derivatives of alkylene carbonates. Of those, preferred are ethylene carbonate and propylene carbonate, and more preferred is propylene carbonate.

The amount of the component (b) to be in the treating liquid is preferably 5-90% by mass, more preferably 10-70% by mass. Defining the amount of the component (b) to fall within the range as above is especially effective for improving the capability of the treating liquid for better dissolution (for promoted removal) of deteriorated photoresist films after dry-etching treatment.

In addition to the above, the treating liquid of the invention contains the component (c), water, as a balance thereof.

Further, the treating liquid of the invention may contain (d) a water-soluble organic solvent. For the component (d) in the invention, preferred are polyalcohols and their derivatives. The polyalcohols include, for example, ethylene glycol, diethylene glycol, propylene glycol, dipropylene glycol, glycerin, 1,2-butylene glycol, 1,3-butylene glycol, 2,3-butylene glycol. Their derivatives are, for example, alkyl-etherified derivatives, concretely including ethylene glycol monomethyl ether, ethylene glycol monoethyl ether, ethylene glycol monobutyl ether, diethylene glycol monomethyl ether, diethylene glycol monoethyl ether, diethylene glycol monobutyl ether, propylene glycol monomethyl ether, dipropylene glycol monomethyl ether, to which, however, the invention should not be limited. Of those, preferred are glycerin and propylene glycol from the viewpoint of improving the corrosion resistance to copper wiring and to a low-dielectric layer.

When the treating liquid contains the component (d), then the content of the component therein is preferably 0.01-30% by mass, more preferably 0.1-20% by mass in view of its corrosion resistance.

The treating liquid for photoresist removal of the invention is used for treating a photoresist film that has been deteriorated through dry-etching treatment through a photoresist pattern formed by selectively exposing a photoresist provided on a support to light followed by developing it. Using the treating liquid of the invention greatly improves the dissolution (for promoted removal) of the deteriorated photoresist film.

In a process of forming a semiconductor substrate, it is desirable that the treatment with the treating liquid for photoresist removal of the invention is followed by additional stripping treatment with a photoresist-stripping liquid. Even a substrate having copper wiring and a low-dielectric layer formed thereon may be favorably treated with the treating liquid of the invention to produce a semiconductor substrate device, irrespective of the presence or absence of plasma-ashing treatment for it. In a case where a substrate is treated with the treating liquid of the invention and then further treated with a photoresist-stripping liquid as in the above, then the treating liquid of the invention may well exhibit its capability for dissolution (for promoted removal) of a deteriorated photoresist film, as compared with a case where one and the same photoresist-stripping liquid is used for stripping treatment alone (or that is, a case where the treatment with the treating liquid of the invention is not effected but the stripping treatment alone is effected), and, as a result, the photoresist-stripping effect can be thereby remarkably improved.

One concrete embodiment of a method for treating a substrate according to the invention is described below, to which, however, the invention should not be limited.

Preferably, the invention is applied to a method of treating a substrate, which includes (I) a step of selectively dry-etching a low-dielectric layer formed on a substrate, through a photoresist pattern serving as a mask as provided on the substrate having at least a copper wire layer and the low-dielectric layer thereon, (II) a step of contacting the substrate after the step (I) with the treating liquid for photoresist removal of the invention, and (III) a step of contacting the substrate after the step (II) with a photoresist-stripping liquid.

### Step (I):

Any known photolithography may be applied to the step. For example, copper (Cu) wiring is formed on a substrate such as silicon wafer, and a low-dielectric layer is formed thereon. If desired, a barrier metal layer or an etching stopper layer may be provided on the Cu wiring as an interlayer, or an insulating layer may be provided to form a multi-layered structure.

The barrier metal layer and the etching stopper layer include Ta layer, TaN layer, SiN layer and SIC layer, but are not limited to these.

Preferably, the low-dielectric layer is formed of a material having a dielectric constant of at most 3. The dielectric constant as meant herein is the proportional constant (∈) in a relational equation of D=∈E where D indicates a magnetic flux density and E indicates a magnetic field intensity.

Preferred examples of the low-dielectric layer are low-dielectric materials (low-k materials), including, for example, carbon-doped silicon oxide (SiOC)-based materials, such as “Black Diamond” (by Applied Materials, Inc.), “Coral” (by Novellus Systems, Inc.), “Aurora” (by Nippon ASM Co., Ltd.); MSQ (methylsilsesquioxane)-based materials such as “OCD T-7”, “OCD T-9”, “OCD T-11”, “OCD T-31”, “OCD T-39” (all by Tokyo Ohka Kogyo Co., Ltd.); HSQ (hydroxysilsesquioxane)-based materials such as “OCD T-12”, “OCD T-32”, (both by Tokyo Ohka Kogyo Co., Ltd.), but these examples are not limitative.

Next, a photoresist composition is applied to the low-dielectric layer and dried thereon, and then this is exposed to light and developed according to known photolithography to form a photoresist pattern.

Not specifically defined, the photoresist composition is preferably any of those generally used for KrF, ArF, F₂ excimer laser or electron rays.

The condition for exposure and development may be suitably determined, depending on the photoresist selected in accordance with the object. For exposure, for example, the photoresist layer may be exposed to a light source capable of emitting active rays such as UV rays, far-UV rays, excimer laser, X-rays or electron rays, such as a low-pressure mercury lamp, a high-pressure mercury lamp, an ultra-high-pressure mercury lamp or a xenon lamp, through a desired mask pattern, or the photoresist layer may be directly patterned by controlling electron rays applied thereto. Next, if desired, the photoresist pattern may be further baked after the exposure (post-exposure baking).

The method of development is not also specifically defined. For example, the photoresist-coated substrate is dipped in a developer for a predetermined period of time, then washed with water and dried (dip development); or a developer is dropwise applied to the surface of the photoresist-coated substrate, and then the substrate is kept as such for a predetermined period of time, then washed with water and dried (paddle development); or the photoresist surface is sprayed with a developer, then washed with water and dried (spray development). These various modes of development may be employed in accordance with the object.

Next, the low-dielectric layer is selectively dry-etched through the formed photoresist pattern serving as a mask, to thereby form via-holes or trenches (for wiring).

### Step (II):

After the dry-etching step as above, the substrate is contacted with the treating liquid of the invention. For their contact, herein employable are a dip method, a paddle method and a spray method like those mentioned hereinabove for treatment with developer. For example, in the following Examples, employed is a treatment condition at 50° C. for 20 minutes, to which, however, the invention should not be limited.

### Step (III):

After the step (II), the substrate is contacted with a photoresist-stripping liquid.

Not specifically defined, the photoresist-stripping liquid is preferably an amine-based stripping liquid that contains a quaternary ammonium hydroxide, a water-soluble organic solvent and water.

The quaternary ammonium hydroxide is preferably one represented by the following general formula (I):

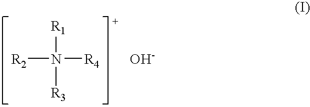

wherein R₁, R₂, R₃ and R₄ each independently represent an alkyl or hydroxyalkyl group having from 1 to 4 carbon atoms.

Concretely, it includes tetramethylammonium hydroxide (=TMAH), tetraethylammonium hydroxide, tetrapropylammonium hydroxide, tetrabutylammonium hydroxide, methyltripropylammonium hydroxide, methyltributylammonium hydroxide, trimethylethylammonium hydroxide, (2-hydroxyethyl)trimethylammonium hydroxide (=choline), (2-hydroxyethyl)triethylammonium hydroxide, (2-hydroxyethyl)tripropylammonium hydroxide, (1-hydroxypropyl)trimethylammonium hydroxide. Of those, preferred are tetramethylammonium hydroxide, tetrabutylammonium hydroxide, tetrapropylammonium hydroxide, methyltributylammonium hydroxide, methyltripropylammonium hydroxide and choline, in view of their ability to strip Cu or Si-containing residues and to strip photoresist. One or more such quaternary ammonium hydroxides may be used herein.

The amount of the quaternary ammonium hydroxide to be in the photoresist-stripping liquid is preferably from 1 to 20% by mass or so, more preferably 2-10% by mass or so.

The water-soluble organic solvent may include sulfoxides, such as dimethyl sulfoxide (=DMSO); sulfones, such as dimethyl sulfone, diethyl sulfone, bis(2-hydroxyethyl)sulfone and tetramethylene sulfone (=sulfolane); amides, such as N, N-dimethylformamide, N-methylformamide, N,N-dimethylacetamide, N-methylacetamide and N,N-diethylacetamide; lactams, such as N-methyl-2-pyrrolidone, N-ethyl-2-pyrrolidone, N-propyl-2-pyrrolidone, N-hydroxymethyl-2-pyrrolidone and N-hydroxyethyl-2-pyrrolidone; imidazolidinones, such as 1,3-dimethyl-2-imidazolidinone, 1,3-diethyl-2-imidazolidinone and 1,3-diisopropyl-2-imidazolidinone; and polyhydric alcohols and derivatives thereof, such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether, diethylene glycol monobutyl ether, propylene glycol monomethyl ether, propylene glycol monoethyl ether, propylene glycol monopropyl ether and propylene glycol monobutyl ether. Among these examples, preferable ones are dimethyl sulfoxide, dimethylimidazolidinone, N-methyl-2-pyrrolidone, diethylene glycol monobutyl ether, sulfolane, N,N-dimethylacetamide and N,N-dimethylformamide. The water-soluble organic solvent may be used either alone or in combination with one another.

In addition, the photoresist-stripping liquid contains water, in which the amount of water is preferably 5-60% by mass or so, more preferably 10-50% by mass or so. The balance of the liquid is the above-mentioned water-soluble organic solvent.

If desired, the photoresist-stripping liquid may further contain a water-soluble amine. The water-soluble amine include alkanolamines, such as monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine and triisopropanolamine; polyalkylenepolyamines, such as diethylenetriamine, triethylenetetramine, propylenediamine, N,N-diethylethylenediamine, 1,4-butanediamine, N-ethyl-ethylenediamine, 1,2-propanediamine, 1,3-propanediamine and 1,6-hexanediamine; aliphatic amines, such as 2-ethyl-hexylamine, dioctylamine, tributylamine, tripropylamine, triallylamine, heptylamine and cyclohexylamine; aromatic amines, such as benzylamine and diphenylamine; and cyclic amines, such as piperazine, N-methyl-piperazine, methyl-piperazine and hydroxyethylpiperazine. Among these, monoethanolamine, 2-(2-aminoethoxy)ethanol and N-methylethanolamine are preferably used from the viewpoint of the strippability of the deteriorated photoresist film and the residue after dry-etching treatment and of the corrosion resistance of the liquid to metal wiring. When the photoresist-stripping liquid contains such a water-soluble amine, then its amount in the liquid is preferably 10-50% by mass or so.

Also if desired, the photoresist-stripping liquid may contain a carboxyl group-having acid compound. Preferred examples of the compound are acetic acid, propionic acid, glycolic acid. When the photoresist-stripping liquid contains such a carboxyl group-having acid compound, then its amount in the liquid is preferably 2-20% by mass or so.

Further if desired, especially when the substrate is not provided with a barrier metal layer or an etching stopper layer as an interlayer, or when the substrate is provided with such a barrier metal layer but is subjected to photoresist-stripping treatment after removal of the barrier metal layer through etching, then it is desirable that at least one corrosion inhibitor selected from aromatic hydroxyl compounds, benzotriazole-based compounds and mercapto group-having compounds is added to the photoresist-stripping liquid, for protecting Cu wiring from corrosion.

The aromatic hydroxyl compounds include phenol, cresol, xylenol, pyrocatechol(=1,2-dihydroxybenzene), tert-butylcatechol, resorcinol, hydroquinone, pyrogallol, 1,2,4-benzenetriol, salicyl alcohol, p-hydroxybenzyl alcohol, o-hydroxybenzyl alcohol, p-hydroxyphenethyl alcohol, p-aminophenol, m-aminophenol, diaminophenol, aminoresorcinol, p-hydroxybenzoic acid, o-hydroxybenzoic acid, 2,4-dihydroxybenzoic acid, 2,5-dihydroxybenzoic acid, 3,4-dihydroxybenzoic acid, 3,5-dihydroxybenzoic acid and gallic acid. Among them, pyrocatechol, pyrogallol and gallic acid, etc. are used with advantage. The aromatic hydroxyl compounds may be used either individually or in combination.

The benzotriazole-based compounds include the ones represented by the following general formula (II):

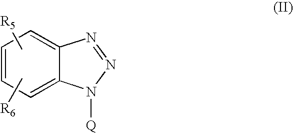

where R₅ and R₆ are each independently a hydrogen atom, a substituted or unsubstituted hydrocarbon group of 1-10 carbon atoms, a carboxyl group, an amino group, a hydroxyl group, a cyano group, a formyl group, a sulfonylalkyl group or a sulfo group; Q is a hydrogen atom, a hydroxyl group or a substituted or unsubstituted hydrocarbon group of 1-10 carbon atoms provided that said hydrocarbon group may have an amide bond or ester bond in the structure, an aryl group or the group represented by the following formula (III):

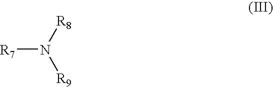

wherein R₇ represents an alkyl group of 1-6 carbon atoms; and R₈ and R₉ are each independently a hydrogen atom, a hydroxyl group or a hydroxyalkyl group or an alkoxyalkyl group of 1-6 carbon atoms.

In the definition of the groups Q. R₅ and R₆ as specified in the present invention, each of the hydrocarbon groups may be an aromatic hydrocarbon group or an aliphatic hydrocarbon group, may be saturated or unsaturated, and may be a linear group or a branched group. Examples of a substituted hydrocarbon group include hydroxyalkyl groups and alkoxyalkyl groups.

In the case where pure Cu is used as the metal conductor on the substrate, it is particularly preferable that Q in the above general formula (II) is a group represented by the formula (III). And in the formula (III), it is preferred that R₈ and R₉ are independently a hydroxyalkyl group or an alkoxyalkyl group of 1-6 carbon atoms.

In the general formula (II), Q preferably forms a water-soluble group and to give specific examples, a hydrogen atom, an alkyl group of 1-3 carbon atoms (i.e., methyl, ethyl, propyl or isopropyl), a hydroxyalkyl group of 1-3 carbon atoms and a hydroxyl group are particularly preferred from the viewpoint of effective protection of inorganic material layer, such as a polysilicon film, an amorphous silicon film, etc. against corrosion.

Specific examples of the benzotriazole-based compounds include benzotriazole, 5,6-dimethylbenzotriazole, 1-hydroxybenzotriazole, 1-methylbenzotriazole, 1-aminobenzotriazole, 1-phenylbenzotriazole, 1-hydroxymethylbenzotriazole, 1-benzotriazole-methyl carboxylate, 5-benzotriazole-carboxylic acid, 1-methoxybenzotriazole, 1-(2,2-dihydroxyethyl)benzotriazole, 1-(2,3-dihydroxypropyl)benzotriazole, and products of “IRGAMET” series marketed from Ciba Specialty Chemicals, such as 2,21-{[(4-methyl-1H-benzotriazol-1-yl)methyl]imino}bisethanol, 2,2′-{[(5-methyl-1H-benzotriazol-1-yl)methyl]imino}bisethanol, 2,2′-{[(4-methyl-1H-benzotriazol-1-yl)methyl]imino}bisethane and 2,2′-{[(4-methyl-1H-benzotriazol-1-yl)methyl]imino}bispropane. Among these compounds, it is particularly preferable to use 1-(2,3-dihydroxypropyl)benzotriazole, 2,2′-{[(4-methyl-1H-benzotriazol-1-yl)methyl]imino}bisethanol, 2,2′-{[(5-methyl-1H-benzotriazol-1-yl)methyl]imino}bisethanol, etc. The benzotriazole-based compounds may be used either individually or in combination.

The mercapto group-having compound is preferably of such a structure that a hydroxyl group and/or a carboxyl group is present in either α-position or β-position on the carbon atom binding to the mercapto group. Specifically, preferred examples of such compound include 1-thioglycerol, 3-(2-aminophenylthio)-2-hydroxypropylmercaptan, 3-(2-hydroxyethylthio)-2-hydroxypropylmercaptan, 2-mercaptopropionic acid and 3-mercaptopropionic acid. Among these, 1-thioglycerol is used with particular preference. Mercapto group-having compounds may be used either singly or in admixture.

When the photoresist-stripping liquid contains any of such aromatic hydroxyl compounds, benzotriazole-based compounds and mercapto group-having compounds, then the amount of the compounds to be in the liquid may vary depending on the type of the photoresist-stripping liquid itself. When the compounds of those groups are combined and used in the liquid, then the amount of each compound is preferably 0.1-10% by mass or so, more preferably 0.5-5% by mass. The uppermost limit of the total amount of the compounds is preferably at most 15% by mass or so.

In addition, the photoresist-stripping liquid for use in the invention may further contain a surfactant, for example, an acetylene alcohol/alkylene oxide adduct prepared by adding an alkylene oxide to acetylene alcohol, for improving the penetrability of the liquid. The acetylene alcohol/alkylene oxide adduct is commercially available, for example, as product series, “Surfynol” (by Air Product and Chemicals, Inc.), and as product series, “Acetylenol” (by Kawaken Fine Chemicals Co., Ltd.), and they are favorably used in the invention. When the photoresist-stripping liquid contains such an acetylene alcohol/alkylene oxide adduct, then its amount in the liquid is preferably 0.05-5% by mass or so, more preferably 0.1-2% by mass or so.

In the step (III), a photoresist-stripping liquid is contacted with the substrate after the step (II), to thereby strip and remove the deteriorated photoresist film after dry-etching treatment. The method for their contact is not specifically defined, for which, in general, employed is any of a dip method, a paddle method or a spray method. Not specifically defined, the stripping time may be enough so far as the intended stripping may be attained within the period of time.

After the stripping step, the substrate may be rinsed with any conventional organic solvent, water or the like and may be dried. The organic solvent is preferably a lower alcohol, more preferably isopropyl alcohol.

The treating liquid of the invention can advantageously be used with all photoresists, whether negative- or positive-working, that can be developed with aqueous alkaline solutions. Such photoresists include, but are not limited to, (i) a positive-working photoresist containing a naphthoquinonediazide compound and a novolak resin, (ii) a positive-working photoresist containing a compound that generates an acid upon exposure, a compound that decomposes with an acid to have a higher solubility in aqueous alkali solutions, and an alkali-soluble resin, (iii) a positive-working photoresist containing a compound that generates an acid upon exposure and an alkali-soluble resin having a group that decomposes with an acid to have a higher solubility in aqueous alkali solutions, and (iv) a negative-working photoresist containing a compound that generates an acid upon illumination with light, a crosslinker and an alkali-soluble resin.

According to the method for treating a substrate of the invention, the solubility (for promoted removal) of a deteriorated photoresist film after dry-etching treatment may be remarkably improved, irrespective of the presence or absence of plasma-ashing treatment, and in addition, the method is effective for making copper wiring and a low-dielectric layer resistant to corrosion.

### EXAMPLES

The invention is described in more detail with reference to the following Examples, to which, however, the invention should not be limited. Unless otherwise specifically indicated, the amount is in terms of % by mass (substantial content, solid content). In Table 1, “PC” means propylene carbonate, and “PG” means propylene glycol.

### 1. Preparation of Photoresist-Stripping Liquid A:

A photoresist-stripping liquid A was prepared according to an ordinary method, containing 10% by mass of tetramethylammonium hydroxide (TMAH), 57.5% by mass of dimethylsulfoxide (DMSO), 30% by mass of water, 1.5% by mass of thioglycerol and 1.0% by mass of 2,2′-([(4-methyl-1H-benzotriazol-1-yl)methyl]imino)bisethanol (=“IR42”).

### 2. Production of Dry-Etched Substrate:

A positive photoresist, TDUR-P722 (by Tokyo Ohka Kogyo Co., Ltd.) was applied to a substrate having copper wiring formed thereon and having an SiOC layer (carbon-doped oxide layer; low-k layer) formed on it, and heated at 140° C. for 90 seconds to form a photoresist layer. This was selectively exposed to light using NSR-S203B (by Nikon Corp.), then further heated at 140° C. for 90 seconds (post-exposure baking treatment), and developed with an aqueous 2.38 mas. % tetramethylammonium hydroxide (TMAH) solution to from a photoresist pattern. Next, the SiOC layer was dry-etched.

After thus dry-etched, the substrate was treated as follows:

### Examples 1 to 4

After dry-etched in the manner as above, the substrate was dipped in a treating liquid shown in Table 1, at 50° C. for 20 minutes, and then rinsed with pure water.

The surface of the thus-treated substrate was observed with SEM (scanning electronic microscope), and evaluated according to the following criteria. The results are shown in Table 1. The low-dielectric layer was not corroded.

### [Dissolution (for Promoted Removal) of Deteriorated Photoresist Film]

◯: Effective for promoted removal of deteriorated photoresist film.

x: Not effective for promoted removal of deteriorated photoresist film.

Next, the substrate was dipped in the photoresist-stripping liquid A, at 50° C. for 20 minutes. Next, this was rinsed with pure water and then dried.

The surface of the thus-treated substrate was observed with SEM (scanning electronic microscope), and evaluated according to the following criteria. The results are shown in Table 1. The low-dielectric layer was not corroded.

### [Strippability of Deteriorated Photoresist Film]

◯: Deteriorated photoresist film was completely removed (with no residue remaining on the substrate).

Δ: Removal of deteriorated photoresist film was incomplete.

x: Deteriorated photoresist film was removed little.

### Comparative Examples 1 to 3

In Comparative Examples 1 and 2, the dry-etched substrate was dipped in a treating liquid as in Table 1 at 50° C. for 20 minutes, then rinsed with pure water, and dipped in the photoresist-stripping liquid A at 50° C. for 20 minutes. Then, this was rinsed with pure water and dried.

In Comparative Example 3, the substrate was, not treated with a treating liquid, dipped in the photoresist-stripping liquid A like in the above, then rinsed with pure water, and dried.

The surface of the thus-treated substrate was observed with SEM (scanning electronic microscope), and evaluated according to the above criteria. The results are shown in Table 1. The low-dielectric layer was not corroded.

TABLE 1

| | | | | | Dissolution (for | |
|---|---|---|---|---|---|---|
| | | | | | promoted removal) | Strippability of |
| | Treating Liquid (mas. %) | | | | of Deteriorated | Deteriorated |
| | Component | Component | Component | Component | Photoresist | Photoresist |
| | (a) | (b) | (c) | (d) | Film | Film |
| Example 1 | H₂O₂ (15) | PC (50) | (35) | — | ◯ | ◯ |
| Example 2 | H₂O₂ (15) | PC (50) | (30) | glycerin (5) | ◯ | ◯ |
| Example 3 | H₂O₂ (10) | PC (50) | (35) | glycerin (5) | ◯ | ◯ |
| Example 4 | H₂O₂ (15) | PC (50) | (30) | PG (5) | ◯ | ◯ |
| Comp. Example 1 | H₂O₂ (35) | — | (65) | — | X | Δ |
| Comp. Example 2 | H₂O₂ (15) | — | (85) | — | X | X |

| | | | |
|---|---|---|---|
| Comp. Example 3 | (treating liquid not used) | — | X |

The invention provides a treating liquid for photoresist removal and a method for treating a substrate using therewith. The treating liquid greatly improves the dissolution (for promoted removal) of a photoresist film deteriorated after dry-etching treatment, irrespective of the presence or absence of plasma-ashing treatment, and its effect is stable, and, in addition, even when the treating liquid is applied to a substrate with copper wiring and a low-dielectric layer formed thereon, it does not have any negative influence on the dielectric constant of the low-dielectric layer, and its corrosion resistance is good.

1. A treating liquid for photoresist removal, containing (a) an oxidizing agent, (b) at least one selected from alkylene carbonates and their derivatives, and (c) water.

2. The treating liquid for photoresist removal as claimed in claim 1, wherein the component (a) is aqueous ozone and/or aqueous hydrogen peroxide.

3. The treating liquid for photoresist removal as claimed in claim 1, wherein the component (a) is aqueous hydrogen peroxide.

4. The treating liquid for photoresist removal as claimed in claim 1, wherein the component (b) is ethylene carbonate and/or propylene carbonate.

5. The treating liquid for photoresist removal as claimed in claim 1, wherein the component (b) is propylene carbonate.

6. The treating liquid for photoresist removal as claimed in claim 1, wherein the component (a) is 0.1-35% by mass, the component (b) is 5-90% by mass, and the component (c) is the balance.

7. The treating liquid for photoresist removal as claimed in claim 1, which further contains (d) a water-soluble organic solvent.

8. The treating liquid for photoresist removal as claimed in claim 7, wherein the component (d) is at least one selected from polyalcohols and their derivatives.

9. The treating liquid for photoresist removal as claimed in claim 7, wherein the component (d) is 0.01-30% by mass.

10. The treating liquid for photoresist removal as claimed in claim 1, which is applied to a substrate having a photoresist film deteriorated after dry-etching treatment thereof, or to a substrate optionally subjected to plasma-ashing treatment after the dry-etching treatment.

11. The treating liquid for photoresist removal as claimed in claim 1, which is used in a photoresist-stripping process that comprises treating a substrate having a photoresist film deteriorated after dry-etching treatment thereof or a substrate optionally subjected to plasma-ashing treatment after the dry-etching treatment, with the treating liquid, and then further treating it with a photoresist-stripping liquid.

12. The treating liquid for photoresist removal as claimed in claim 10, wherein the substrate has at least copper wiring and a low-dielectric layer formed thereon.

13. A method for treating a substrate, which comprises treating a substrate having a photoresist film deteriorated after dry-etching treatment thereof or a substrate optionally subjected to plasma-ashing treatment after the dry-etching treatment, with the treating liquid for photoresist removal of claim 1, and then treating it with a photoresist-stripping liquid for stripping off the photoresist.

14. The method for treating a substrate as claimed in claim 13, wherein the photoresist-stripping liquid is an amine-based photoresist-stripping liquid that contains a quaternary ammonium hydroxide, a water-soluble organic solvent and water.

15. The method for treating a substrate as claimed in claim 14, wherein the photoresist-stripping liquid further contains at least one corrosion inhibitor selected from aromatic hydroxyl compounds, benzotriazole-based compounds and mercapto group-having compounds.
